(19) United States
(12) Patent Application Publication
(10) Pub. No.: US 2014/0092561 A1
(43) Pub. Date: Apr. 3, 2014

(54) HANDHELD MOBILE DEVICE AND BACK COVER FOR THE SAME

(71) Applicant: NVIDIA CORPORATION, Santa Clara, CA (US)

(72) Inventors: Qiang CHEN, Shenzhen (CN); Zhi TAN, Shenzhen (CN); Xianpeng HUANG, Suzhou (CN)

(73) Assignee: NVIDIA CORPORATION, Santa Clara, CA (US)

(21) Appl. No.: 14/035,636

(22) Filed: Sep. 24, 2013

(30) Foreign Application Priority Data
Sep. 29, 2012 (CN) 201210375720.7

(51) Int. Cl. H05K 7/20

(52) U.S. Cl. CPC H05K 7/20509
USPC 361/720; 361/704

(57) ABSTRACT

In various embodiments, a handheld mobile device and back cover for the same are provided. The back cover for a handheld mobile device comprises: a back cover body having a first surface and a second surface opposite to the first surface; and a heat dissipating plate fixed to the first surface of the back cover body; wherein a hole is provided in a region of the back cover body corresponding to the heat dissipating plate. The heat dissipating plate covers the heat-generating elements on the circuit board, and the heat dissipating plate is partly exposed to the outside via the corresponding hole in the back cover body, such that the heat dissipating plate eliminates the partial heat-generating points and dissipates heat to the outside via the hole effectively.

### CROSS-REFERENCE TO RELATED APPLICATION

This patent application claims the benefit and priority of the co-pending Chinese Patent Application No. 201210375720.7, filed on Sep. 29, 2012, by Qiang CHEN et al., Attorney Docket Number P12838307, which is hereby incorporated by reference in its entirety.

### BACKGROUND

Handheld mobile devices, such as cell phones, tablet computers, etc. generate plenty of heat during operation. Specifically, chips such as a processor, internal memories, etc. and elements such as batteries in handheld mobile devices generate heat and become partial heat sources. However, the housings of most of the handheld mobile devices are made of heat isolating material or poor heat conductor material so that partial overheating might be caused in the space enclosed by the housing. If the heat is transferred to the outer surface of the handheld mobile device, then increased temperatures might be generated on the surface of the handheld mobile device, such that users might feel uncomfortable when touching or holding the handheld mobile device.

### SUMMARY

Various embodiments of the present invention are related to a handheld mobile device and back cover for the same.

In one embodiment of the invention, a back cover for a handheld mobile device is provided which comprises: a back cover body having a first surface and a second surface opposite to the first surface; and a heat dissipating plate fixed to the first surface of the back cover body; wherein a hole is provided in a region of the back cover body corresponding to the heat dissipating plate.

Preferably, in an embodiment, the heat dissipating plate is tightly affixed to the first surface of the back cover body.

Preferably, in an embodiment, the heat dissipating plate is adhered, fused, ultrasonic welded, or threaded-connected by screws to the first surface of the back cover body.

Preferably, in an embodiment, the hole includes a plurality of holes, and the holes are distributed evenly on the back cover body.

Preferably, in an embodiment, the shape and size of each of the holes are the same, with the area of each of the holes being less than 2 mm² (square millimeters).

Preferably, in an embodiment, the distance between adjacent holes is more than 2.5 mm (millimeters).

Preferably, in an embodiment, the holes are circular-shaped.

Preferably, in an embodiment, the heat dissipating plate is made of a metallic material.

Preferably, in an embodiment, the back cover body is made of a poor heat conductor material.

In another embodiment of the invention, a handheld mobile device is provided which comprises: a circuit board; and a back cover, the back cover includes: a back cover body having a first surface and a second surface opposite to the first surface; and a heat dissipating plate fixed to the first surface of the back cover body; wherein a hole is provided in a region of the back cover body corresponding to the heat dissipating plate; wherein the heat dissipating plate covers heat-generating elements on the circuit board.

Preferably, in an embodiment, thermal gap filler pads are provided between the heat dissipating plate and the heat-generating elements, with the thermal gap filler pads adhered on surfaces of the heat-generating elements facing the heat dissipating plate.

Preferably, in an embodiment, the heat dissipating plate is tightly affixed to the first surface of the back cover body.

Preferably, in an embodiment, the heat dissipating plate is adhered, fused, ultrasonic welded, or threaded-connected by screws to the first surface of the back cover body.

Preferably, in an embodiment, the hole includes a plurality of holes, and the holes are distributed evenly on the back cover body.

Preferably, in an embodiment, the shape and size of each of the holes are the same, with the area of each of the holes being less than 2 mm², and the distance between the adjacent holes being more than 2.5 mm.

Preferably, in an embodiment, the holes are circular-shaped.

Preferably, in an embodiment, the heat dissipating plate is made of a metallic material.

Preferably, in an embodiment, the back cover body is made of a poor heat conductor material.

The following are the effectiveness of the present invention: the back cover for a handheld mobile device of the invention comprises a back cover body and a heat dissipating plate fixed to the first surface of the back cover body, and a hole is provided in a region of the back cover body corresponding to the heat dissipating plate. It could be understood that in the handheld mobile device, the heat dissipating plate covers heat-generating elements on the circuit board and is partly exposed to the outside via the corresponding hole in the back cover body, such that the heat dissipating plate eliminates the partial heat-generating points and dissipates heat to the outside via the hole effectively. Thus, there will not be overheating and partial overheating on the surface of the handheld mobile device, so a comfortable temperature is maintained. When a user touches or holds the handheld mobile device, he/she will contact the second surface of the back cover body opposite to the first surface and will not feel the discomfort of high temperature.

Additional features and advantages of various embodiments in accordance with the invention will be set forth in the description that follows, and in part will be apparent from the description, or may be learned by practice of various embodiments in accordance with the invention. The advantages of various embodiments in accordance with the invention will be realized and attained by the structure particularly pointed out in the written description and claims hereof as well as the appended drawings.

It is to be understood that both the foregoing general description and the following detailed description are exemplary and explanatory and are intended to provide further explanation of various embodiments in accordance with the invention as claimed.

While particular embodiments in accordance with the invention have been specifically described within this Summary, it is noted that the invention and the claimed subject matter are not limited in any way by these embodiments.

### BRIEF DESCRIPTION OF THE DRAWINGS

The accompanying drawings are included to provide a further understanding of various embodiments in accordance with the invention, and are incorporated in and constitute a part of this specification. The drawings illustrate various embodiments of the invention and, together with the description, serve to explain the principles of various embodiments in accordance with the invention. In the drawings,

FIG. 1 illustrates a schematic front view of the back cover for a handheld mobile device in accordance with an embodiment of the present invention;

FIG. 2 illustrates a schematic rear view of the back cover for a handheld mobile device in accordance with an embodiment of the present invention; and

FIG. 3 illustrates a schematic front view of the back cover for the handheld mobile device in accordance with an embodiment of the present invention, with a portion of the back cover thereof removed to show the interior of the handheld mobile device.

### DETAILED DESCRIPTION

Reference will now be made in detail to various embodiments in accordance with the invention, examples of which are illustrated in the accompanying drawings. While the invention will be described in conjunction with various embodiments, it will be understood that these various embodiments are not intended to limit the invention. On the contrary, the invention is intended to cover alternatives, modifications and equivalents, which may be included within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details or with equivalents thereof. In other instances, well known methods, procedures, components, and circuits have not been described in detail as not to unnecessarily obscure aspects of the invention.

Various embodiments in accordance with the present invention relate generally to electronic equipment and, in particular, to a handheld mobile device and back cover for the same.

Example embodiments are described herein in the context of a handheld mobile device and back cover for the same. Those of ordinary skill in the art will realize that the following description is illustrative only and is not intended to be in any way limiting. Other embodiments will readily suggest themselves to those skilled in the art having the benefit of this disclosure. Reference will now be made in detail to implementations of the example embodiments as illustrated in the accompanying drawings. The same reference numbers will be used to the extent possible throughout the drawings and the following description to refer to the same or like items.

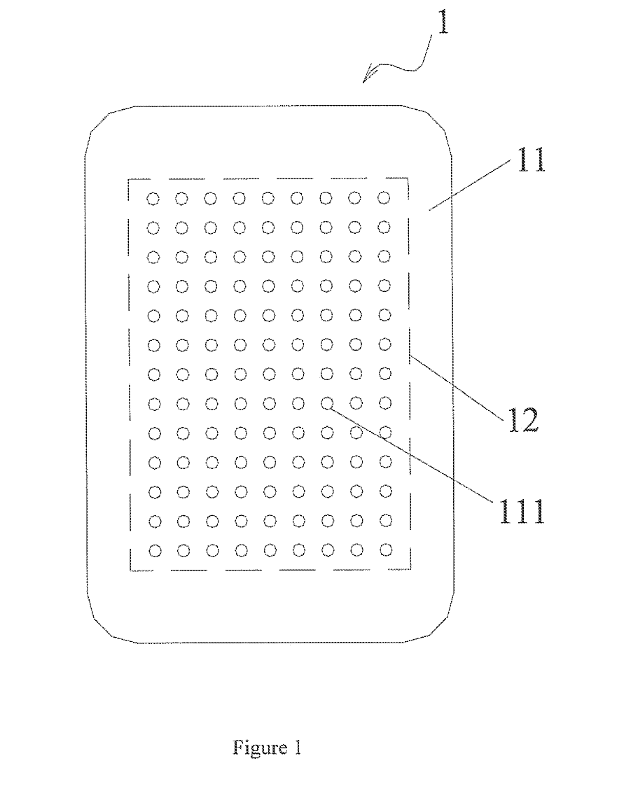

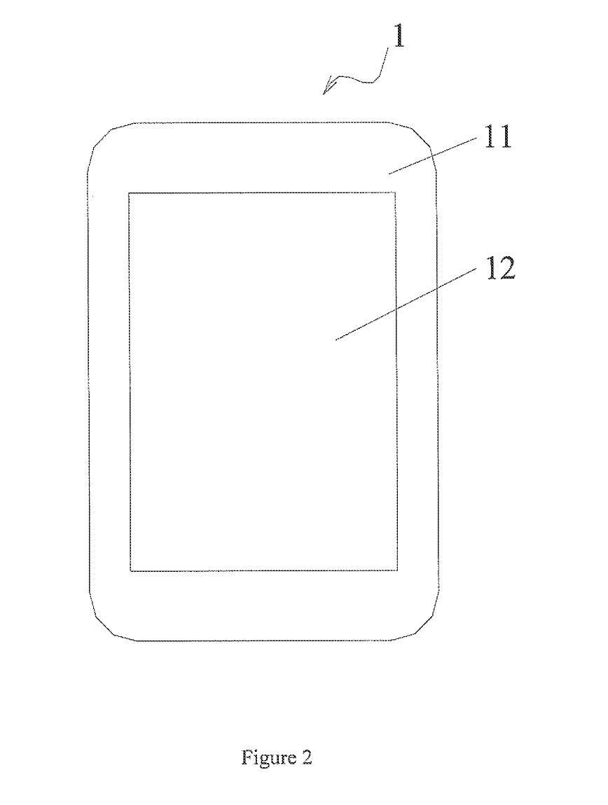

As shown in FIG. 1 and FIG. 2, the back cover 1 for a handheld mobile device in accordance with the embodiment of the present invention comprises a back cover body 11 and a heat dissipating plate 12. The back cover body 11 has a first surface which is shown in FIG. 2 and a second surface opposite to the first surface which is shown in FIG. 1. In FIG. 1 the heat dissipating plate 12 is shown by dashed lines. When used in a handheld mobile device, the first surface forms a surface facing towards the interior of the handheld mobile device, while the second surface forms the back surface of the handheld mobile device. The heat dissipating plate 12 is fixed to the first surface of the back cover body 11, so that when used in a handheld mobile device, the heat dissipating plate 12 face towards the interior of the handheld mobile device and covers the heat-generating elements. As shown in FIG. 1, a hole 111 is provided in a region of the back cover body 11 corresponding to the heat dissipating plate 12.

It can be understood that when the back cover 1 is used as the back cover of a handheld mobile device, the heat dissipating plate 12 thereof covers the heat-generating elements on the circuit board of the handheld mobile device, and the heat dissipating plate 12 is partly exposed to the outside via the corresponding hole 111 in the back cover body 11, such that the heat dissipating plate 12 eliminates the partial heat-generating points and dissipates heat to the outside via the hole 111 effectively. Thus, there will not be overheating and partial overheating on the surface of the handheld mobile device, so a comfortable temperature is maintained. When a user touches or holds the handheld mobile device, he/she will contact the second surface of the back cover body 11 opposite to the first surface and will not feel the discomfort of high temperature.

It can be understood by those skilled in the art that the heat dissipating plate 12 could be made of any suitable heat conducting material, and preferably, in the present embodiment, the heat dissipating plate 12 can be made of a metallic material which is easily processed and manufactured with low cost. In addition, the back cover body 11 could also be made of materials which are suitable to be used as a back cover of a handheld mobile device. But preferably, in the present embodiment, the back cover body 11 is made of a poor heat conductor material, e.g., plastic, such that the user would not feel high temperature when touching the back cover (e.g., the second surface of the back cover).

Since the back cover for a handheld mobile device is typically made of a poor heat conductor material (such as plastic, etc.) having low strength and is easily curved and damaged, the back cover is required to be made thick. However, the back cover 1 for a handheld mobile device further comprises a heat dissipating plate 12 fixed to the back cover body 11. And if the heat dissipating plate 12 is made of metallic material, the heat dissipating plate 12 with high strength functions to support the back cover, such that the whole back cover 1 could be made thinner and the thickness of the whole handheld mobile device is reduced when the back cover 1 is used in the whole handheld mobile device.

In an embodiment, most of the surface of the heat dissipating plate 12 may be spaced apart from the first surface of the back cover body 11. But preferably, in an embodiment, the heat dissipating plate 12 is tightly affixed to the first surface of the back cover body 11, so as to act as a sealing plate preventing external dust, moisture, etc. from entering in.

The heat dissipating plate 12 could be tightly affixed to the back cover body 11 in various suitable manners. Preferably, in an embodiment, the heat dissipating plate 12 may be adhered, fused, or ultrasonic welded on the first surface of the back cover body 11. Or preferably, in an embodiment, the heat dissipating plate 12 may be threaded-connected to the first surface of the back cover body 11 by screws. For example, if the heat dissipating plate 12 is rectangular, each of its four corners may be provided with a screw and the heat dissipating plate 12 may be threaded-connected to the back cover body 11 by the four screws.

Preferably, as shown in FIG. 1, in the present embodiment, the above mentioned hole 111 on the back cover body 11 includes a plurality of holes distributed evenly on the back cover body 11. Thus the heat dissipating could be more efficient and even.

More preferably, as shown in FIG. 1, in the present embodiment, the shape and size of each hole 111 of the plurality of holes 111 are the same with the area of each of the holes 111 being less than 2 mm². It could be understood that holes with the same shape and size could be easily processed and could facilitate even heat dissipation, while smaller area of the hole could ensure that when the hand of the user touches the second surface of the back cover 1, it would not contact the heat dissipating plate 12 which may have high temperature and feel uncomfortable.

In addition, preferably, in an embodiment, the distance between the adjacent holes is more than 2.5 mm. Greater distance between holes could also ensure that when the hand of the user touches the second surface of the back cover 1, it would not contact the heat dissipating plate 12 which may have high temperature and feel uncomfortable.

The hole 111 may take any suitable shape, preferably, in the present embodiment, as shown in FIG. 1, the hole 111 has a circular shape which is easily processed.

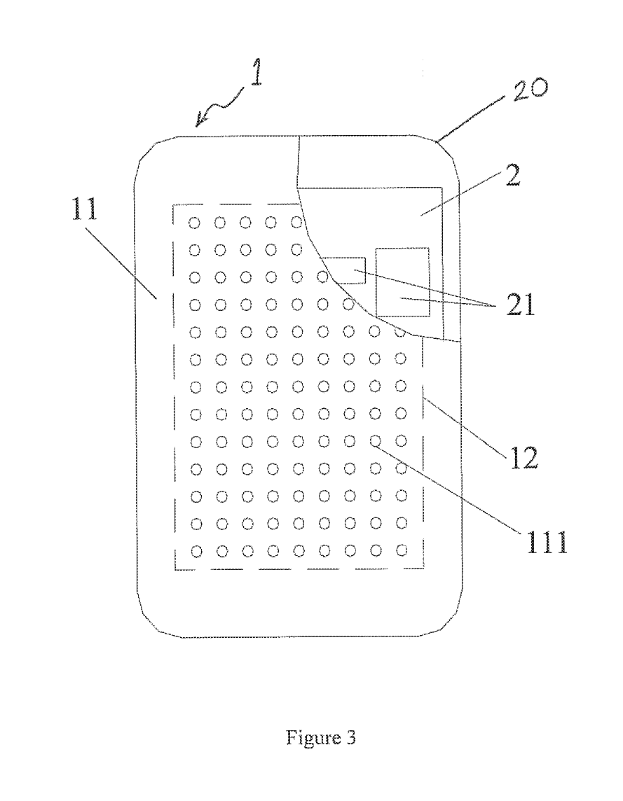

As shown in FIG. 3, the handheld mobile device 20 in accordance with an embodiment of the present invention comprises a circuit board 2 and a back cover 1. Of course, the handheld mobile device 20 also comprises any other components in the handheld mobile device of the prior art, such as screen, etc., which are not changed in various embodiments of the present invention and are not described in detail in context. As described above, the back cover 1 comprises a back cover body 11 and a heat dissipating plate 12. The back cover body 11 has a first surface and a second surface opposite to the first surface. The FIG. 3 shows the second surface of the back cover body 11 (e.g., the back surface of the handheld mobile device 20). The heat dissipating plate 12 shown by dashed lines is fixed to the first surface of the back cover body 11, so as to face towards the circuit board 2 within the handheld mobile device 20 and cover the heat-generating elements 21 (e.g., chips such as processor, internal memories, etc. and elements such as batteries) on the circuit board 2 in the handheld mobile device 20. As is shown in FIG. 3, a hole 111 is provided in a region of the back cover body 11 corresponding to the heat dissipating plate 12.

It can be understood that the heat dissipating plate 12 covers the heat-generating elements 21 on the circuit board 2 of the handheld mobile device 20, and the heat dissipating plate 12 is partly exposed to the outside via the corresponding hole 111 in the back cover body 11, such that the heat dissipating plate 12 eliminates the partial heat-generating points and dissipates heat to the outside via the hole 111 effectively. Thus, there will not be overheating and partial overheating on the surface of the handheld mobile device 20, so a comfortable temperature is maintained. When a user touches or holds the handheld mobile device 20, he/she will contact the second surface of the back cover body 11 opposite to the first surface and will not feel the discomfort of high temperature.

As described above, the heat dissipating plate 12 could be made of any suitable heat conducting material, and preferably, in the present embodiment, the heat dissipating plate 12 can be made of a metallic material which is easily processed and manufactured with low cost. In addition, the back cover body 11 could also be made of materials which are suitable to be used as a back cover of a handheld mobile device. But preferably, in the present embodiment, the back cover body 11 is made of a poor heat conductor material, e.g., plastic, such that the user would not feel high temperature when touching the back cover (e.g., the second surface of the back cover).

Since the back cover for a handheld mobile device is typically made of a poor heat conductor material (such as plastic, etc.) having low strength and is easily curved and damaged, the back cover is required to be made thick. However, in the handheld mobile device 20 in accordance with an embodiment of the present invention, the back cover 1 further comprises a heat dissipating plate 12 fixed to the back cover body 11. And if the heat dissipating plate 12 is made of metallic material, the heat dissipating plate 12 with high strength functions to support the back cover, such that the whole back cover 1 could be made thinner and the thickness of the whole handheld mobile device 20 is reduced.

The heat dissipating plate 12 may directly cover the heat-generating elements 21 on the circuit board 2. However, in this embodiment, the top surfaces of all of the heat-generating elements 21 on the circuit board 2 are at the same level, so as to ensure the heat dissipating plate 12 is in contact with all of the heat-generating elements 21. Preferably, in the present embodiment, thermal gap filler pads (not shown in the figures and are made of gap filling interface materials of Laird Corporation) are provided between the heat dissipating plate 12 and the heat-generating elements 21, with the thermal gap filler pads adhered on surfaces of the heat-generating elements 21 facing the heat dissipating plate 12. Since the thermal gap filler pads have heat conducting performance and are flexible to be deformed under the pressing action between the heat dissipating plate 12 and the heat-generating elements 21, it is ensured that the heat dissipating plate 12 is in contact with all of the heat-generating elements 21 even when the top surfaces of the heat-generating elements 21 are not at the same level, thus the heat dissipating plate 12 functions to dissipate heat effectively.

In the handheld mobile device 20, in an embodiment, most of the surface of the heat dissipating plate 12 may be spaced apart from the first surface of the back cover body 11. But preferably, in an embodiment, the heat dissipating plate 12 is tightly affixed to the first surface of the back cover body 11, so as to act as a sealing plate preventing external dust, moisture, etc. from entering in.

The heat dissipating plate 12 could be tightly affixed to the back cover body 11 in various suitable manners. Preferably, in an embodiment, the heat dissipating plate 12 may be adhered, fused, or ultrasonic welded on the first surface of the back cover body 11. Or preferably, in an embodiment, the heat dissipating plate 12 may be threaded-connected to the first surface of the back cover body 11 by screws. For example, if the heat dissipating plate 12 is rectangular, each of its four corners may be provided with a screw and the heat dissipating plate 12 may be threaded-connected to the back cover body 11 by the four screws.

Preferably, as shown in FIG. 3, in the present embodiment, the above mentioned hole 111 on the back cover body 11 includes a plurality of holes distributed evenly on the back cover body 11. Thus the heat dissipating could be more efficient and even.

More preferably, as shown in FIG. 3, in the present embodiment, the shape and size of each hole 111 of the plurality of holes 111 are the same with the area of each of the holes 111 being less than 2 mm² and the distance between the adjacent holes is more than 2.5 mm. It could be understood that holes with same shape and size could be easily processed and could facilitate even heat dissipating, while smaller area of the holes and greater distance between holes could ensure that when the hand of the user touches the second surface of the back cover 1, it would not contact the heat dissipating plate 12 which may have high temperature and feel uncomfortable.

The hole 111 may take any suitable shape, preferably, in the present embodiment, as shown in FIG. 3, the hole 111 has a circular shape which is easily processed.

It should be appreciated that various modifications, adaptations, and alternative embodiments thereof may be made within the scope and spirit of the present invention. The invention is further defined by the following claims.

The foregoing descriptions of various specific embodiments in accordance with the invention have been presented for purposes of illustration and description. They are not intended to be exhaustive or to limit the invention to the precise forms disclosed, and many modifications and variations are possible in light of the above teaching. The invention is to be construed according to the Claims and their equivalents.

What is claimed is:

1. A back cover for a handheld mobile device, said back cover comprising:
a back cover body; and
a heat dissipating plate fixed to a surface of said back cover body;
wherein said back cover body defines a hole in a region corresponding to said heat dissipating plate.

2. The back cover of claim 1, wherein said heat dissipating plate is adhered or connected to said surface of said back cover body.

3. The back cover of claim 1, wherein said heat dissipating plate is fused or ultrasonic welded to said surface of said back cover body.

4. The back cover of claim 1, wherein said back cover body defines a plurality of holes, and said plurality of holes are distributed on said back cover body.

5. The back cover of claim 4, wherein the area of each of said plurality of holes is less than 2 mm².

6. The back cover of claim 4, wherein the distance between adjacent holes is more than 2.5 mm.

7. The back cover of claim 4, wherein said plurality of holes are circular-shaped.

8. The back cover of claim 1, wherein said heat dissipating plate comprises a metallic material.

9. The back cover of claim 1, wherein said back cover body comprises a poor heat conductor material.

10. A handheld mobile device comprising:
a circuit board; and
a back cover comprising:
a back cover body; and
a heat dissipating plate fixed to a surface of said back cover body;
wherein said back cover body defines a hole in a region corresponding to said heat dissipating plate;
wherein said heat dissipating plate covers a heat-generating element on said circuit board.

11. The handheld mobile device of claim 10, further comprising a thermal gap filler pad located between said heat dissipating plate and said heat-generating element.

12. The handheld mobile device of claim 11, wherein said thermal gap filler pad is adhered on a surface of said heat-generating element facing said heat dissipating plate.

13. The handheld mobile device of claim 10, wherein said heat dissipating plate is adhered, fused, ultrasonic welded, or connected by screws to said surface of said back cover body.

14. The handheld mobile device of claim 10, wherein said back cover body defines a plurality of holes, and said plurality of holes are distributed on said back cover body.

15. The handheld mobile device of claim 14, wherein the area of each of said plurality of holes is less than 2 mm².

16. The handheld mobile device of claim 14, wherein the distance between adjacent holes is more than 2.5 mm.

17. The handheld mobile device of claim 14, wherein said plurality of holes are circular-shaped.

18. The handheld mobile device of claim 10, wherein said heat dissipating plate comprises a metallic material.

19. The handheld mobile device of claim 10, wherein said back cover body comprises a poor heat conductor material.

20. A back cover for a handheld mobile device, said back cover comprising:
a back cover body having a first surface and a second surface opposite to said first surface; and
a heat dissipating plate fixed to said first surface of said back cover body;
wherein said back cover body defines a hole in a region corresponding to said heat dissipating plate.
